(19) United States
(12) Patent Application Publication
(10) Pub. No.: US 2021/0094800 A1
(43) Pub. Date: Apr. 1, 2021

(54) SYSTEMS AND METHODS FOR MONITORING THE INTEGRITY OF BELTS IN ELEVATOR SYSTEMS

(71) Applicant: thyssenkrupp Elevator Innovation and Operations GmbH, Essen (DE)

(72) Inventors: Andrew EVERT, Atlanta, GA (US); James WATTS, Atlanta, GA (US)

(73) Assignee: thyssenkrupp Elevator Innovation and Operations GmbH, Essen (DE)

(21) Appl. No.: 16/585,747

(22) Filed: Sep. 27, 2019

(51) Int. Cl. B66B 7/12; G01N 27/83; B66B 3/00; B66B 5/00

(52) U.S. Cl. CPC B66B 7/123; G01N 27/83; B66B 5/0031; B66B 5/0025; B66B 3/002

(57) ABSTRACT

Systems and methods may be used to monitor the integrity of a belt of an elevator system. Many buildings nowadays do not have the luxury of being able to regularly take an elevator system out of service to perform a giant magneto-resistance (GMR) scan of an entire length of the belt from which an elevator car is suspended. One method to avoid this inconvenience involves performing GMR scans of segments of the belt during the course of everyday passenger traffic and compiling data associated with different segments into a complete GMR profile for the belt. To determine whether the belt contains an irregularity, the GMR profile may then be compared to one or more baseline GMR profiles that were acquired previously, ideally at a time when the belt was known not to contain any irregularities.

### FIELD

The present disclosure generally relates to elevators, including systems and methods for efficiently and effectively monitoring the integrity of load bearing members in suspension belts.

### BACKGROUND

Suspension rope systems for raising and lowering elevator cars comprise a belt having multiple steel load bearing members embedded within a coating. Each load bearing member typically includes a plurality of interwoven steel wire strands. Such suspension rope systems are critical components upon which safety and productivity often depend. Most often the belts suspend one or more elevator cars and/or one or more counterweights via one or more sheaves. Deterioration of the belt and its load bearing members adversely affects tension strength of the belt. The tension strength of a belt depends on various factors such as the belt's cross-sectional area. When one or more load bearing members of the belt stretch, tear, or permanently bend, those load bearing members are at least weakened. Consequently, the effective tension-bearing cross-sectional area of the belt is reduced. Deterioration can occur in many ways, including via normal wear and tear, impact, fatigue, and/or corrosion.

At one point, belts were only replaced upon visual detection of an irregularity. Because belts can be very long and can comprise many individual load bearing members, though, basing a conclusion about the integrity of the belt purely on a visual inspection is a questionable practice, especially considering that deterioration may occur internally and may not be outwardly detectable. For this reason amongst others, elevator manufacturers and maintenance providers eventually began replacing belts at periodic milestones (e.g., every five years) and/or cyclic milestones (e.g., every 500K cycles, with a cycle occurring each time an elevator car changes directions), if not before then upon visual identification of an irregularity.

More recently, some jurisdictions have demanded that elevator manufacturers and maintenance providers monitor the integrity of belts in suspension rope systems more actively. For instance, one jurisdiction has interpreted an elevator safety code such that a belt should be retired from service when its residual breaking strength reaches 60% of the belt's initial minimum breaking strength rating. However, there has thus far been a lack of guidance as to how to track residual breaking strength. It should be understood that 60% is a floor and that Applicant has historically retired belts and will continue to retire belts long before the 60% threshold. This jurisdiction has also opined that cycle counting—as a sole means for tracking residual breaking strength of a belt—does not suffice.

Thus a need exists for systems and methods that can accurately, efficiently, and effectively monitor the integrity of load bearing members of a belt in an elevator system.

### SUMMARY

Most recently, the elevator industry has turned to giant magneto-resistance (GMR) technology for detecting irregularities in load bearing members of belts. In short, the belt can be moved through a magnetic field, and a GMR sensor can detect changes in the magnetic field that are due to irregularities at certain locations in the load bearing members. Electromagnetic scanning, acoustic scanning, and other non-invasive forms of scanning may also be used in connection with the teachings of the present disclosure. If an irregularity is detected, the elevator car may be taken out of service immediately and the belt retired.

One method for monitoring the integrity of a belt in an elevator system with a GMR monitoring system comprises performing GMR scans of various segments of the belt in the course of transporting passengers between floors of a building. The scanned segments of the belt typically correspond to less than an entirety of the length of the belt. Nonetheless, data from the GMR scans may be compiled into a GMR profile representing the full length, or at least a substantial majority of the length, of the belt and analyzed to determine whether the belt contains an irregularity. Such a method is particularly advantageous where the building does not have the luxury of taking an elevator out of service to run a complete GMR scan of the belt from top to bottom.

Further, GMR scanning, compiling subsets of a complete GMR profile, and analyzing GMR profiles may be repeated periodically, such as daily, weekly, or monthly, for instance. Hence the integrity of the belt may be tracked over time with comparative analyses. And if the elevator car does not travel to or pass by all of the floors of the building due to passenger traffic during a given period, the elevator car may be taken out of service temporarily towards the end of the period while the monitoring system scans segments of the belt that have yet to be scanned.

Analyzing the GMR profile may entail comparing GMR values associated with points along the length of the belt to corresponding GMR values from one or more GMR profiles that were acquired prior to the most-recent GMR profile. In cases where numerous GMR profiles are used for comparison, the GMR values may be averaged or median values used. Ideally, the previously-acquired GMR profiles are acquired at a time when the belt is known not to contain any irregularities, such as before the elevator car was ever suspended from the belt or just before the elevator system was approved for passenger use. In some instances, each GMR value from a GMR profile may be compared to the average or median value of all GMR values for that GMR profile, rather than being compared to the respective GMR value of one or more different, previously-acquired GMR profiles.

Another aspect of the present disclosure concerns systems and methods for identifying high-wear sections of the belt. If high-wear sections can be identified, a higher percentage of resources can be allocated to monitoring those sections of the belt, whether via GMR scanning, visual inspections, etc. One such method involves storing position versus time data in a storage medium for an elevator car that travels throughout a hoistway. The method may further involve determining which section of the belt engages with one or more sheaves for the full range of movement of the elevator car in the hoistway. Based on the position versus time data and at least one high-wear factor, an elevator control system can identify a high-wear section of the belt. High-wear factors include, for example, a quantity of different ways in which each section of the belt is bent during operation of the elevator system, a frequency with which each section of the belt transitions between being straight and being engaged with one of the sheaves, a total amount of time that each section of the belt spends idly wrapped around any sheave, and a frequency with which each section of the belt is engaged with any sheave when the elevator car accelerates or decelerates.

### BRIEF DESCRIPTION OF THE DRAWINGS

FIG. 1A is a schematic view of an example elevator system.

FIG. 1B is cross-sectional view of an example belt of the elevator system of FIG. 1A.

FIG. 2 is a block diagram of an example belt monitoring system.

FIG. 3A is a schematic view depicting a first segment of the example belt of FIG. 1B, which does not include any irregularities, passing through a magnetic field of an example GMR sensor unit.

FIG. 3B is a schematic view depicting a second segment of the example belt of FIG. 1B, which includes an irregularity, passing through the magnetic field of the example GMR sensor unit.

FIG. 4A is perspective view of an example handheld monitoring system.

FIG. 4B is a perspective view of the example handheld monitoring system of FIG. 4A shown with an example belt.

FIG. 5 is schematic view of another example elevator system with two example belt monitoring systems.

FIG. 6 is a flowchart depicting an example method for periodically monitoring the integrity of a belt in an elevator system.

FIG. 7 is a schematic view of another example elevator system with 2:1 gearing.

FIG. 8 is a flowchart depicting an example method for identifying high-wear sections of a belt in an elevator system.

### DETAILED DESCRIPTION

Although certain example methods and apparatuses are described herein, the scope of coverage of this patent is not limited thereto. On the contrary, this patent covers all methods, apparatuses, and articles of manufacture fairly falling within the scope of the appended claims either literally or under the doctrine of equivalents. Moreover, those having ordinary skill in the art will understand that reciting “a” element or “an” element in the appended claims does not restrict those claims to articles, apparatuses, systems, methods, or the like having only one of that element, even where other elements in the same claim or different claims are preceded by “at least one” or similar language. Similarly, it should be understood that the steps of any method claim need not necessarily be performed in the order in which they are recited, unless so required by the context of the claims. In addition, all references to one skilled in the art shall be understood to refer to one having ordinary skill in the art. With respect to the drawings, it should be understood that not all components are drawn to scale. Furthermore, those having ordinary skill in the art will understand that the various examples disclosed herein should not be considered in isolation. Rather, those with ordinary skill in the art will readily understand that the disclosure relating to some examples may be combined with and/or equally applicable to the disclosure relating to other examples.

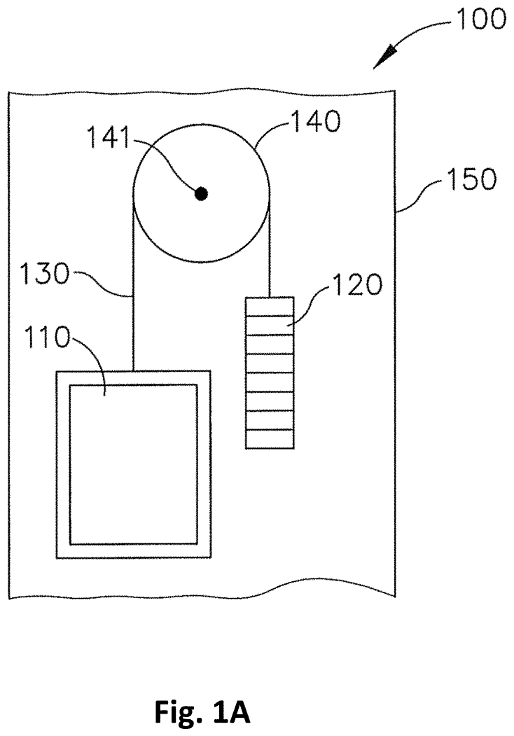

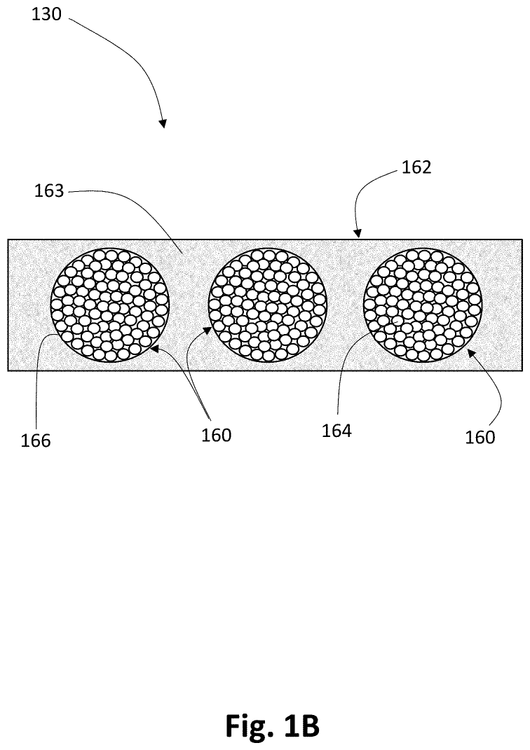

With reference to FIG. 1A, an example elevator system 100 may include a car 110 and a tension unit 120 connected by a belt 130. A drive sheave 140 may be turned by a hoisting motor 141 to move the belt 130. Movement of the belt 130 may translate the car 110 and the tension unit 120 through a hoistway 150. The tension unit 120 can include aids for creating tension in the belt 130. The tension created provides travel control of the belt 130 and, thereby, travel control of the elevator car 110. In some examples, the tension unit 120 may include a passive weight system such as a counterweight or even another elevator car. Alternatively, the tension unit 120 can include a mechanical tensioning system such as a spring system or a high traction system with grooved belt and spool designs, for example. In some examples the elevator system 100 may be configured as a drum elevator where the belt 130 is wound and unwound about a drum to raise and lower the car 110 through the hoistway 150. In still other cases, the elevator system 100 may be configured as a roped hydraulic elevator system where the tension unit 120 is used with a hydraulic drive by having the car 110 connected with the tension unit 120 via the belt 130. In view of the teachings herein, a multitude of other configurations for the elevator system 100 will be apparent to those of ordinary skill in the art.

As shown in FIG. 1B the belt 130 may be configured as a suspension member and may include at least one load bearing member 160 (e.g., a cable) disposed within a coating 162. In some instances, the coating 162 may comprise a matrix material 163, a polyurethane material, and/or some other form of envelope that surrounds and separates the load bearing members 160, as shown in FIG. 1B. Each load bearing member 160 may be comprised of a plurality of wire strands 164 that contain magnetic material. In some cases, each load bearing member 160 may include a sheath 166 disposed around the plurality of wire strands 164. Suspension members can include, for example and without limitation, flat belts, steel wire ropes, cog belts, round ropes, and the like that are coated or uncoated. As explained below, giant magneto-resistance (GMR) can operate through non-magnetic materials such as polyurethane coatings. The GMR effect can therefore be utilized with both uncoated magnetic materials and magnetic materials that are coated in non-magnetic materials.

Analyzing the structural integrity and remaining life of the belt 130 can help ensure safe operation of the elevator system 100. Degradation of the belt 130 can result from, as one example, cyclic bending around sheaves when the elevator car 110 moves through the hoistway. Fortunately, the belt 130 can be scanned or monitored for degradation. As explained above, visual inspection methods for monitoring the belt 130 can be limited by the coating 162 of the belt 130, and the load bearing members 160 of the belt 130 can experience damage that is not always outwardly detectable. Hence the present disclosure concerns monitoring systems that comprise magnetic field producers and GMR sensor units capable of identifying irregularities in the belt 130, as disclosed in U.S. Patent Publication No. US2015/0239708A1 entitled “System and Method for Monitoring a Load Bearing Member” and filed on Feb. 25, 2014, which is hereby incorporated by reference in its entirety.

The example GMR sensor units disclosed herein and in U.S. Patent Publication No. US2015/0239708A1 are capable of identifying the position of an irregularity along the length, width, and depth of the belt 130. Targeted investigations can reduce the amount of investigation necessary for identifying defects or damage in the load-bearing members 160 and for determining the integrity of the belt 130. Moreover, the GMR sensor units are also capable of determining a degree of an irregularity. Irregularities may include, for example, diameter diminution of cables or wires, broken wires due to fretting wear and stress fatigue, holes, voids, roughing, corrosion, fractures, deformation, manufacturing defects, localized flaws, loss of metallic cross-sectional area, loss of metallic volume defects, and/or other forms of damage.

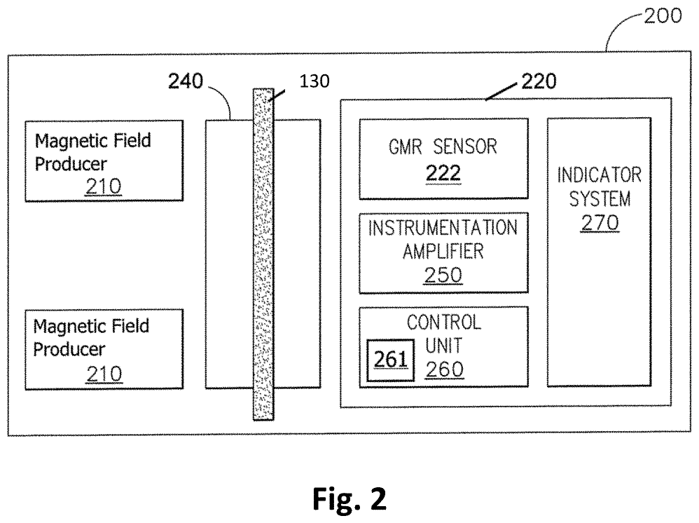

FIG. 2 depicts one example monitoring system 200 that includes one or more magnetic field producers 210 and a GMR sensor unit 220. The belt 130 may be positioned within a magnetic field 240 of the magnetic field producer 210. The GMR sensor unit 220 is capable of detecting variations in the magnetic field 240 caused by interactions with the belt 130. To this end, in some examples the monitoring system 200 may include a GMR sensor 222, an instrumentation amplifier 250, a control unit 260, and an indicator system 270. The GMR sensor unit 220 may contain a single GMR sensor 222 or an array of sensors. The need for and size of a sensor array may be based on the size and geometry of the belt 130 and/or the number, size, composition, and/or geometry of the load bearing members 160 of the belt 130.

Further, the amplifier 250 may amplify a signal produced by the GMR sensor 222 in response to variations in the magnetic field 240. The amplified signal can be transmitted to a control unit 260. The control unit 260 can store information regarding signals from the GMR sensor 222 in a storage medium 261 for immediate or subsequent processing. In addition or in the alternative, the control unit 260 can activate the indicator system 270 to report a concerning GMR signal. The control unit 260 can also communicate the GMR signal to an elevator control system, an operator, building management, a maintenance schedule, etc. Communication can occur without limitation via telephone lines, Ethernet cables, or other wired telecommunications equipment; cellular communications; local area networks (LANs); wireless protocols such as Bluetooth or Wi-Fi; and streaming to electronic devices such as handhelds, computers, smart phones, and the like. The communication can be through secure and/or proprietary communication protocols. It should be understood that the control unit 260 may in some cases be understood to be part of the elevator control system.

In the example shown in FIG. 2, the magnetic field producers 210 are located separate from the GMR sensor unit 220. In other examples, though, the magnetic field producers 210 may be constituents of the GMR sensor unit 220. For instance, the magnetic field producers 210 and the GMR senor unit 220 may be located in a common housing unit. In some instances, the housing unit may guide the belt 130 as the belt 130 moves. The housing unit can be placed directly against the belt 130 or can be spaced apart from the belt 130. In some examples the belt 130 may pass through an aperture or an open-ended slot of the housing unit. Hence the housing unit can help maintain a constant position of the belt 130 relative to the GMR sensor unit 220 as the belt 130 moves relative to the GMR sensor unit 220.

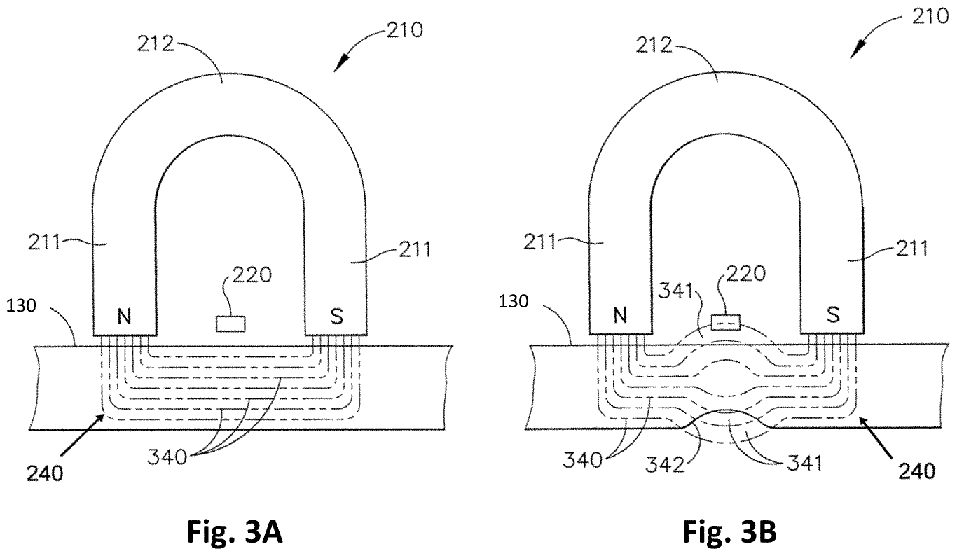

In the example shown in FIGS. 3A and 3B, a magnetic field 240 is produced by the magnetic field producer 210, which includes two elongated magnets 211. In some examples, the magnets 211 have no energy requirement to activate the magnetic field 240. A metal plate 212 can operate as a magnetic conductor to complete a magnetic flux loop of the magnetic field producer 210. A portion of a set of flux lines 340 representing the magnetic field 240 goes through a magnetic field path generally defined by a shape and geometry of the magnetic portion of the belt 130. The magnetic flux 340 leaks or deviates from a standard magnetic field path when an irregularity 342, which is present in the segment of belt 130 in FIG. 3B but not in the segment of belt 130 in FIG. 3A, interacts with the magnetic field 240 produced by the magnetic field producer 210. The magnetic field 240 produced by the magnetic field producer 210 is capable of penetrating a full depth of the belt 130. Irregularities 342 to any magnetic portion of the belt 130 affect the magnetic flux 340 and create flux leakage 341 that is detectable by the GMR sensor unit 220, in some cases, in the form of a high voltage reading. The GMR sensor unit 220 may be structured and positioned to sense the magnetic flux leakage 341.

It should be understood that the GMR sensor unit 220 can detect the magnetic flux leakage 341 while the belt 130 is stationary or while the belt 130 is moving, although typically the GMR sensor unit 220 is operated when the belt 130 is moving. In that vein, those having ordinary skill in the art will understand that the GMR sensor unit 220 may perform a higher quality scan of the belt 130 when the belt 130 is moving at a slow, constant speed relative to the GMR sensor unit 220. In some examples, a slow, constant speed may be ½ m/s. Nonetheless, by sensing the magnetic flux leakage 341, the GMR sensor unit 220 can communicate to an elevator control system the location of the irregularity 342, the magnitude of the irregularity 342, the type of irregularity 342, the time at which the irregularity 342 was detected, and so on. In most cases, the belt 130 will be taken out of service immediately if any irregularity 342 is detected. If the measured flux leakage 341 is abnormal but does not quite rise to the level of an irregularity 342, the belt 130 may first be visually inspected and/or rescanned.

In some examples, the elongated magnets 211 of the magnetic field producer 210 are aligned relative to the belt 130 and the GMR sensor unit 220. In other examples, the GMR sensor unit 220 can be aligned relative to the magnetic field 240 and the belt 130. In one example, the GMR sensor unit 220 may be aligned perpendicular to the belt 130 and to the magnetic field 240, as an axis of sensitivity of the GMR sensor unit 220 may be orthogonal to a longitudinal axis of the load-bearing members 160. Further, a degree of distortion or noise of the signal from the GMR sensor unit 220 may correspond to a degree of perpendicularity of the components. For example, distortion or noise may increase as a degree of perpendicularity between the GMR sensor unit 220 and the belt 130 decreases. Notwithstanding, those having ordinary skill in the art will understand that signals from a GMR sensor 222 can be conditioned and/or amplified by an instrumentation amplifier 250 to counteract noise, distortion, and other defects.

The monitoring system 200 may provide periodic or continuous monitoring of the moving belt 130 used in driving the elevator system 100. The monitoring system 200 may be configured such that a majority of the belt 130 is positionable proximate to the monitoring system 200, and specifically, the GMR sensor unit 220, during operation of the elevator system 100. The monitoring system 200 may detect irregularities within the load bearing members 160 of the belt 130 without necessarily contacting the belt 130 directly. Also, in some examples, the monitoring system 200 may be configured along a portion of the belt 130 between ends of the belt 130 and/or between termination devices that hold the belt 130.

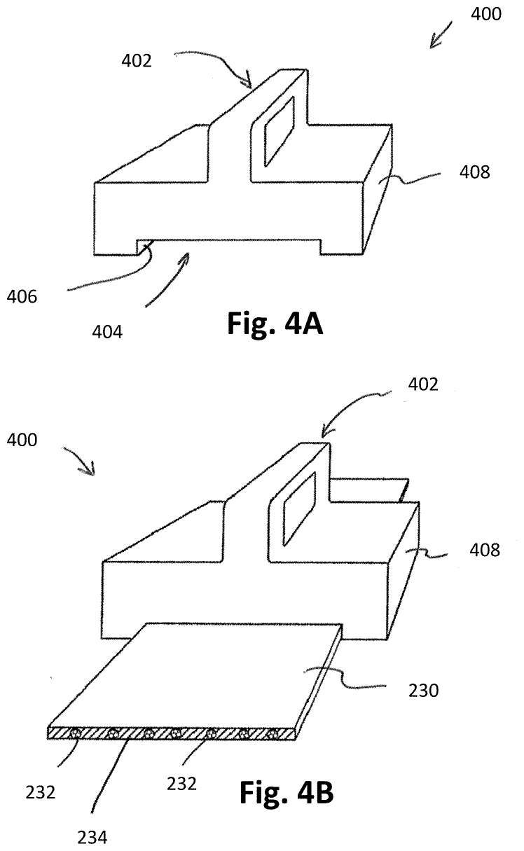

FIGS. 4A and 4B illustrate an example handheld monitoring system 400 that can be used to monitor a belt 230 with load bearing members 232 surrounded by a matrix material 234. It should be understood that the handheld monitoring system 400 could also be used to monitor the belt 130 shown in the preceding figures. Nevertheless, the handheld monitoring system 400 is configured to be portable such that a technician has a portable monitoring system that can be used to monitor the belt 230 in an elevator system. In some cases there may be no other monitoring system installed and the handheld monitoring system 400 may be used alone. In most cases, however, the handheld monitoring system 400 can be used to scan segments of the belt 230 that do not travel past a fixed monitoring system and/or as a form of redundancy to verify the location and degree of any irregularities identified by another monitoring system.

The handheld monitoring system 400 may in some examples include a handle 402 and a U-shaped recess 404. The handle 402 may be disposed in a location that makes the handheld monitoring system 400 easy to grasp. For example, the handle 402 may be located opposite the recess 404. The recess 404 may have a shape, such as the U-shape shown in FIGS. 4A and 4B, that complements a shape of the belt 230. For instance, the example belt 230 that is shown is generally flat and thus fits within the U-shaped recess 404 such that the U-shaped recess 404 guides the belt 230. Sidewalls 406 of a housing 408 of the handheld monitoring system 400 that define the U-shaped recess 404 may serve as positioning members that guide the belt 230 as the belt 230 passes by the handheld monitoring system 400. In the example shown in FIG. 4B, for instance, the belt 230 is guided by three sidewalls 406 of the housing 408 that define the recess 404. In other cases, though, more or fewer positioning members can be used to guide the belt 230. In view of the teachings herein, a multitude of other ways to guide and/or position the belt 230 relative to the housing 408 of the handheld monitoring system 400 will be apparent to those of ordinary skill in the art.

The handheld monitoring system 400 may be a portable, or more-portable, version of the monitoring system 200 shown in FIG. 2 and hence may include some or all of the components of the example monitoring system 200. In some cases, however, one or more of these components may be provided separate from the handheld monitoring system 400. For example, in some instances a magnetic field producer such as the magnetic field producer 210 can be provided in a separate device that is positionable on an opposite side of the belt 230 from the handheld monitoring system 400.

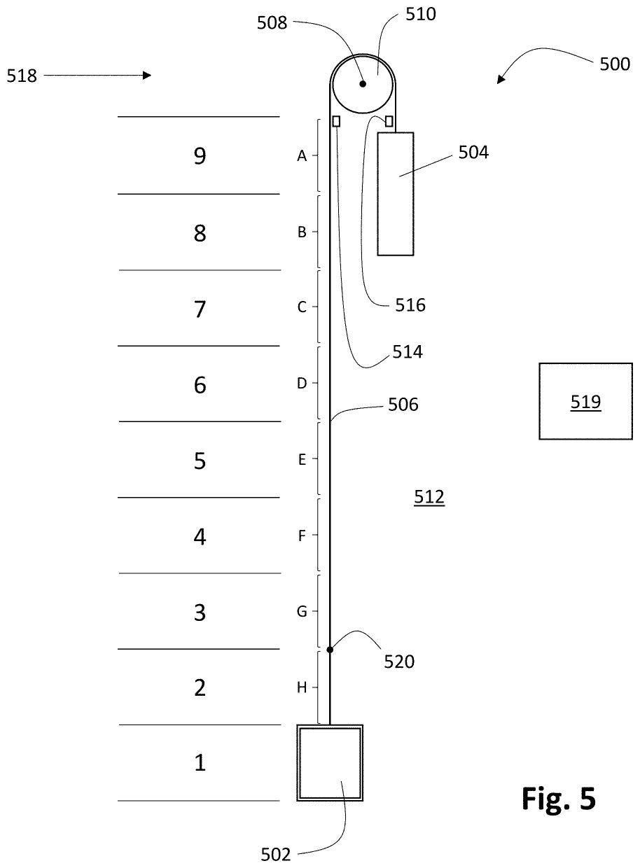

In addition to replacing belts at least at cyclic and/or periodic milestones, as discussed further above, the present disclosure proposes using these example monitoring systems to perform GMR scans of a belt either continuously or periodically (e.g., one or more times per hour, half-day, day, week, month, etc.) to monitor the integrity of load bearing members of the belt. If an irregularity in a load bearing member is identified prior to the next cyclic or periodic milestone, the belt can be replaced immediately. This concept will be described in further detail below with respect to FIG. 5.

FIG. 5 schematically depicts yet another example elevator system 500. As an aside, those having ordinary skill in the art will understand how the present disclosure applies equally to elevator systems of much greater complexity than elevator systems 100, 500. Notwithstanding, similar to the elevator system 100 shown in FIG. 1A, the elevator system 500 in FIG. 5 may include an elevator car 502 and a tension unit 504 connected by a belt 506. The tension unit 504 here is configured as a counterweight, and the belt 506 includes segments A-H. A hoisting motor 508 may turn a drive sheave 510 to move the belt 506, which in turn moves the car 502 in a hoistway 512 between the floors of a building where “1” represents the first floor, “2” represents the second floor, and so on. For the sake of simplicity, FIG. 5 only depicts nine floors. However, those having ordinary skill in the art will understand that the present disclosure is applicable to buildings with many more floors as well as to building with less floors. Likewise, although numerals are used to designate the floors in FIG. 5, it should be understood that a multitude of other arrangements are possible, such as where floor 1 corresponds to a pit, floors 2 and 3 correspond to an underground parking garage, floor 4 corresponds to a lobby, etc.

In some examples, a first monitoring system 514 and, in some cases, a second monitoring system 516 fixed at a top 518 of the hoistway 512 may perform periodic or continuous GMR monitoring. The first and second monitoring systems 514, 516 may be positioned at the drive sheave 510 to minimize the likelihood of vibration in the belt 506. The first and second monitoring systems 514, 516 may be similar to the example monitoring system 200 shown in FIG. 2 and may include at least some, if not all, of the components of the monitoring system 200.

The elevator system 500 may employ the second monitoring system 516 because the first monitoring system 514 may not necessarily be able to scan the entire length of the belt 506, even when moving the elevator car 502 between the first (bottom) floor 1 and the ninth (top) floor 9. For instance, when the elevator car 502 is positioned at the first floor 1, a “remainder” of the belt 506 (i.e., the portion of the belt 506 outside of segments A-H) that extends upward from the first monitoring system 514, over the drive sheave 510, and downward to the tension unit 504 will not pass the first monitoring system 514 during normal operation of the elevator system 500. However, the second monitoring system 516 may be configured to scan the remainder of the belt 506 during normal operation. As an alternative to the second monitoring system 516, the elevator system 500 may utilize a handheld monitoring system, such as the example handheld monitoring system 400 shown in FIGS. 4A and 4B, for scanning the remainder of the belt 506 that is inaccessible to the first monitoring system 514. The GMR data sets from the various different monitoring systems may then be combined into a single GMR profile for the belt 506.

In one example, an elevator control system causes the elevator car 502 to travel from the first (bottom) floor 1 of the building to the ninth (top) floor 9. With respect to the first monitoring system 514, a magnetic field producer can generate a magnetic field that segments A-H of the belt 506 pass through while a GMR sensor detects and relays GMR data to a control unit for storage or immediate processing. With respect to the second monitoring system 516, a magnetic field producer can generate a magnetic field that the remainder of the belt 506 passes through while a GMR sensor detects and relays GMR data to a control unit for storage or immediate processing. By combining the GMR data from both the first and second monitoring systems 514, 516, the elevator control system may be provided with a GMR profile that indicates the presence (or lack thereof) of any irregularities. Of course, this GMR scan could also be completed by causing the elevator car 502 to travel from the ninth floor 9 down to the first floor 1.

The present disclosure contemplates a variety of methods by which such a GMR scan could occur. In one method, for instance, if a passenger places a call at the first floor 1 to travel to the ninth floor 9 (or vice versa), the GMR scan could occur while the elevator car 502 is transporting that passenger. The GMR scan could alternatively or additionally occur while the elevator car 502 is traveling to pickup that passenger, which goes without saying below. If no such passenger call is placed during a time period in which a GMR scan is required, the elevator car 502 may be taken out of service temporarily towards the end of the time period while the elevator control system schedules the GMR scan. Ideally, the elevator car 502 would be temporarily taken out of service and the GMR scan run during off-peak hours when convenient, such as when demand for the elevator car 502 is least (e.g., overnight), such as when staging elevator cars higher in a building towards the end of a workday, or such as when staging elevator cars lower in a building towards the beginning of a workday, as examples. In some cases, the elevator system 500 may reference passenger call statistics to identify time(s) when demand is least.

Some advantages to conducting a GMR scan while the elevator car 502 is temporarily out of service is that GMR scans can be performed under ideal conditions, which will enhance the consistency and quality of the GMR data. By way of example, varying the amount of weight attributable to passengers in the car 502 from one scan to the next can adversely affect the consistency of GMR data. Taking the car 502 out of service and thus clearing passengers from the car 502 before conducting each GMR scan eliminates this variable. As another example, GMR scans yield more accurate results when the pace at which the GMR scans are conducted is slow and constant. Using the non-limiting example from further above, ½ m/s may under some circumstances be an ideal, slow, constant speed at which to move the elevator car 502 relative to the first and second monitoring systems 514, 516 during a GMR scan.

In some examples, an elevator control system 519 of the elevator system 500 or a control unit of the GMR sensor unit of the first and/or second monitoring systems 514, 516 may compare a second GMR profile of the belt 506 from a second time period to a first GMR profile of the belt 506 from a first time period. If the second GMR profile differs from the first GMR profile in any statistically significant manner, an irregularity may exist in the belt 506. In this example, the second GMR profile may be regarded as the “current” or “most-recent” GMR profile. In some instances, the comparison may involve comparing the most-recent GMR profile of the belt 506 separately to more than one previously-acquired GMR profile in an effort to identify any irregularities. In yet other examples, the most-recent GMR profile may be compared to a baseline GMR profile that was acquired either when the belt 506 was first produced at a manufacturing facility, when the belt 506 was first installed in the hoistway 512 prior to attachment of the elevator car 502 and the tension unit 504, when the elevator car 502 and the tension unit 504 were first attached to the belt 506 after installation, or when the elevator system 500 was initially commissioned for service after installation (which may follow verification/validation testing). In still other examples, the most-recent GMR profile of the belt 506 may be compared to an average of a plurality of previously-acquired GMR profiles of the belt 506. In some cases, the plurality of previously-acquired scans may have been acquired at the time that the belt 506 was first put into operation, or may be based on two or more of the baseline GMR profiles identified above.

There are a variety of ways in which the elevator control system 519 of the elevator system 500 or a control system of a GMR sensor unit of one of the monitoring systems 514, 516 can determine if a variation between two GMR profiles that have been compared (or one GMR profile compared with an average of several other GMR profiles) is statistically-significant enough to conclude that one or more irregularities exist in the belt 506. After all, even successive GMR profiles acquired minutes apart under the same conditions will almost surely vary, at least to some extent. As one example, each recorded GMR value from the length of the belt 506 may be compared to a corresponding GMR value from a previously-acquired baseline GMR profile. Hence, with respect to FIG. 5, a current GMR value for a point 520 where segment G of the belt 506 meets segment H may be compared to a previously-acquired baseline GMR value for the point 520. If the current GMR value for the point 520 differs from the baseline GMR value for the point 520 by more than 15%, for example and without limitation, an irregularity may be deemed to exist and the belt 506 may need to be replaced. If the current GMR value for the point 520 differs from the baseline GMR value for the point 520 by more than 10% but not quite 15%, for example and without limitation, the elevator car 502 may be taken out of service and the point 520 may be rescanned immediately under ideal conditions to determine whether the concerning GMR value was erroneous and whether the elevator car 502 can be recommissioned. In some instances, a visual inspection may also be required prior to recommissioning the elevator car 502. Further, if the current GMR value for the point 520 differs from the baseline GMR value for the point 520 by more than 5% but not quite 10%, for example and without limitation, a rescan and/or visual inspection of the point 520 may be scheduled during off-peak hours to evaluate whether an irregularity exists at the point 520.

As another similar example, the baseline GMR values for an irregularity-free belt may be 0V. If the current GMR value for the point 520 is 1.5V or higher, for example and without limitation, an irregularity may be deemed to exist and the belt 506 may need to be replaced. If the current GMR value for the point 520 is between 1.0V and 1.5V, for example and without limitation, the elevator car 502 may be taken out of service and the point 520 may be rescanned immediately under ideal conditions to determine whether the concerning GMR value was erroneous and whether the elevator car 502 can be recommissioned. In some instances, a visual inspection may also be required prior to recommissioning the elevator car 502. Further, if the current GMR value for the point 520 is between 0.5V and 1.0V, for example and without limitation, a rescan and/or visual inspection of the point 520 may be scheduled during off-peak hours to evaluate whether an irregularity exists at the point 520.

As still another example, the current GMR value for the point 520 may be compared to the median (or additionally or alternatively the average) of a plurality of previously-acquired GMR values (e.g., the first fifty GMR values acquired for the point 520, for instance). If the current GMR value for the point 520 differs from the median of the plurality of previously-acquired GMR values by more than two standard deviations (2σ), the belt 506 may be deemed to have an irregularity at the point 520—or at the very least a visual inspection and/or rescan(s) of the point 520 may be scheduled to evaluate whether an irregularity likely exists at the point 520.

In yet other examples, GMR values for the belt 506 may be compared to other GMR values from the same GMR profile generated from the same GMR scan. Thus the most-recent GMR value for the point 520 along the belt 506 may be compared to the median (or additionally or alternatively the average) of all GMR values recorded in the most-recent GMR scan. If the GMR value for the point 520 differs from the median of all GMR values from the most-recent GMR scan by more than 2.5 standard deviations (2.5σ), again, for example and without limitation, the belt 506 may be deemed to have an irregularity at the point 520 and be deemed to need immediate replacing. In another example, the GMR value for the point 520 may be compared with a plurality of GMR values that were acquired in the same GMR scan from locations along the belt 506 that are most-proximate to the point 520. Hence the GMR value for the point 520 may be compared to the median (or additionally or alternatively the average) of one-hundred GMR values, for instance, acquired from segment G and one-hundred GMR values, for instance, acquired from segment H in the same scan.

Those having ordinary skill in the art will understand that these examples are not limiting, but instead are merely illustrative Likewise, those having ordinary skill in the art will understand that certain outlier GMR values, especially those that are not reproducible upon rescanning, may be excluded during the analysis of a GMR profile or may be excluded from GMR profiles that will be referenced in the future.

Some buildings may not have the luxury of periodically taking an elevator car out of service to perform GMR scans. This may be the case in buildings with only one elevator, in taller buildings where GMR scans can take upwards of thirty minutes, in buildings where passenger demand for an elevator system over a period is nearly uniform, and so on. In cases such as these, a method may be used to compile a complete GMR profile for the belt 506 based on separate GMR data sets acquired during the same period that correspond, respectively, to various segments A-H of the belt 506.

To this end and with continued reference to FIG. 5, consider a case where during the same period a first person travels in a first run from the first floor 1 up to the third floor 3, a second person travels in a second run from the ninth floor 9 down to the fifth floor 5, and a third person travels in a third run from the second floor 2 up to the sixth floor 6. The first monitoring system 514 of the elevator system 500 may perform a GMR scan of segments A and B of the belt 506 while the elevator car 502 transports the first person from the first floor 1 to the third floor 3. The first monitoring system 514 may perform a GMR scan of segments H, G, F, and E while the elevator car 502 transports the second person from the ninth floor 9 to the fifth floor 5. And the first monitoring system 514 may perform a GMR scan of segments B, C, D, and E while the elevator car 502 transports the third person from the second floor 2 to the sixth floor 6. Meanwhile, the second monitoring system 516 may also perform GMR scans during these three passenger runs. While the first person is being transported, for example, the second monitoring system 516 may perform a GMR scan of the remainder of the belt 506 extending between the first monitoring system 514 and the tension unit 504 as shown in FIG. 5. The second monitoring system 516 may perform a GMR scan of (approximately in FIG. 5) segments F, E, D, and C while the second passenger is being transported. Similarly, the second monitoring system 516 may perform a GMR scan of (approximately in FIG. 5) segments A, B, C, and D while the third passenger is being transported. At this stage, GMR data has thus been acquired for all segments of the belt 506.

During some periods the elevator car 502 may not necessarily travel to all floors based on passenger demand alone. If towards the end of a period (e.g., where the period if 75%, 80%, 85%, 90%, 95%, 97.5%, or 99% complete) the elevator car 502 has not traveled to the ninth floor 9, for example, there will not be any GMR data set corresponding to segment H of the belt 506. In this case, the elevator car 502 could be taken out of service temporarily to travel to the ninth floor 9 while the first monitoring system 514 GMR scans segment H of the belt 506.

Thereafter, the elevator control system 519 of the elevator system 500 or the control unit of the GMR sensor unit of the first and/or second monitoring systems 514, 516 may compile a GMR profile for the belt 506 based on the various acquired GMR data sets. Duplicative data points (e.g., two GMR values corresponding to the point 520 along the belt 506) may be averaged and, in cases where enough data is acquired, outlier data points may be selectively discarded. Once compiled, this most-recent/current GMR profile may then be analyzed for irregularities as explained above.

Yet in further examples, the first and second monitoring systems 514, 516 may be configured to continuously scan the belt 506 when the elevator car 502 is moving, as opposed to periodically scanning the length of the belt 506. Although continuous monitoring will generate much duplicative GMR data, for purposes of generating a GMR profile duplicative data points for locations along the belt 506 may be averaged and outlier data points may be selectively discarded. Alternatively, the elevator control system 519 or the control unit of one of the monitoring systems 514, 516 may continuously compare the GMR data being measured with some previously-acquired GMR profile, with a baseline GMR profile, and/or with GMR data measured from the same time period from other locations along the belt 506 (or an average or median thereof). If an irregularity is detected at any point, the elevator system 500 may be taken out of service and an operator, building management, a maintenance schedule, etc. may be notified.

It should be understood that there may be quality control checks involving the first and second monitoring systems 514, 516. As one example, GMR values acquired from the point 520 along the belt 506 that originate from the first monitoring system 514 may be compared with GMR values that originate from the second monitoring system 516 and are also acquired from the point 520. If the comparison reveals that for the same points along the belt 506 the first and second monitoring systems 514, 516 are recording noticeably different GMR values (e.g., values that differ by ±2.5%, 5%, 7.5%, 10%), then the elevator system 500 may report that the first and/or second monitoring systems 514, 516 need calibration, repair, replacement, etc. As a second example, the first and second monitoring systems 514, 516 may be tested prior to being put into operation and then intermittently thereafter to ensure that they are properly detecting irregularities. One way to achieve this is to have the monitoring systems 514, 516 GMR scan segments of decommissioned belts that are known to have irregularities of different sorts. An improperly-working monitoring system may then be re-calibrated, repaired, replaced, etc.

It should be understood that segment A may also be referred to as a “first segment,” segment B may also be referred to as a “second segment,” and so on. Moreover, although the belt 506 is described as having specific segments A-H, it should be understood that the segments A-H are primarily for facilitating the explanation of the present disclosure. In reality the elevator control system 519 of the elevator system 500 and/or the control units of the monitoring systems 514, 516 “know” precisely which points are positioned at the respective monitoring systems 514, 516 based on the location of the elevator car 502, without reference to the segments A-H. Likewise, the elevator control system 519 and/or the control units of the monitoring systems 514, 516 know which points along the belt 506 have been or have not been scanned during a period, without reference to the segments A-H. What's more, the elevator control system 519 and/or the control units of the monitoring systems 514, 516 are also able to account for stretch of the belt 506—however minimal—over time, over periods of high and low usage, and over different seasons of the year where different coefficients of thermal expansion take effect, for example.

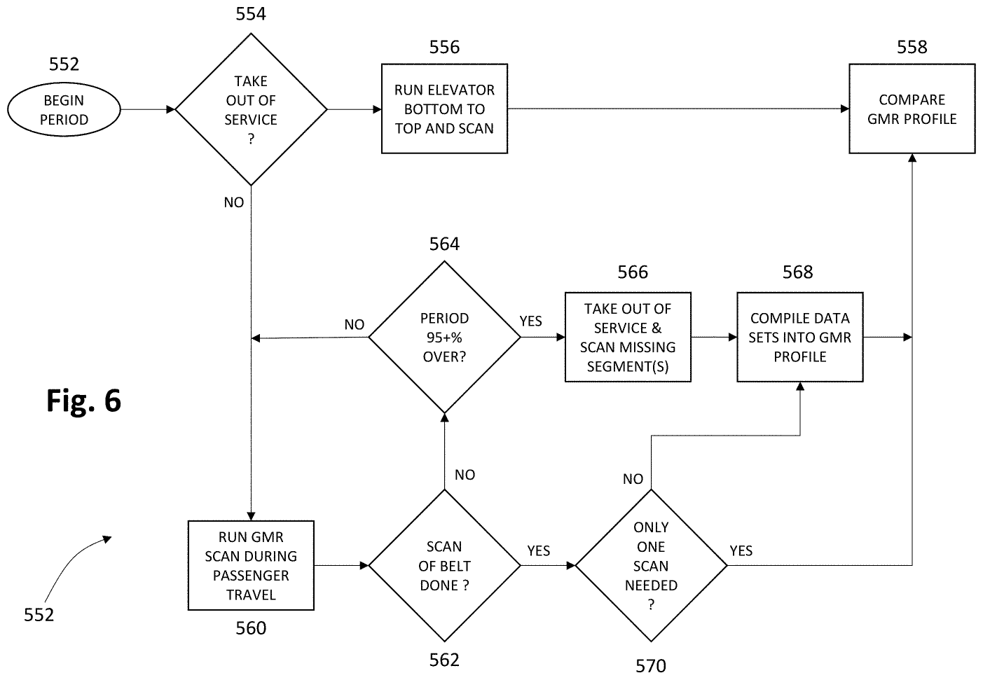

FIG. 6 shows an example method 550 for periodically monitoring the integrity of a belt. The method 550 includes at least some of the aspects of the present disclosure described above, and hence many of the aforementioned details will not be repeated. Furthermore, the method 550 is not limited to the steps recited below or those shown in FIG. 6, but may involve a variety of additional or alternative steps that all fall within the scope of the present disclosure. When a period begins 552, an elevator control system may determine 554 whether an elevator car can be taken out of service long enough to run a full GMR scan. If the elevator car can be taken out of service, perhaps during off-peak hours, the GMR scan can be run 556 while the elevator car travels from a bottom of a hoistway to a top of the hoistway, or vice versa. The GMR profile that is acquired may then be compared 558 intrinsically or to other, previously-acquired GMR profiles, as disclosed above.

However, if the elevator car cannot be taken out of service during a period, a monitoring system may perform a GMR scan 560 when the elevator car transports a passenger. If the scan of the belt is not complete 562, the elevator control system may query 564 whether the period is substantially complete (e.g., at least 75%, 80%, 85%, 90%, 95%, or 97.5%). If the period is not substantially complete, the monitoring system may continue to perform GMR scans 560 as more passengers are transported. If the scan of the belt is not yet complete 562 and the period is substantially complete 564, the elevator may be taken out of service and the monitoring system may scan the one or more segments of the belt that have not yet been scanned 566. The numerous GMR data sets corresponding to various segments of the belt may then be compiled 568 into a single GMR profile and subsequently compared 558 for identification of an irregularity.

By contrast, when the scan of the belt is completed 562 based on one or more scans that occurred during passenger travel 560, the elevator control system may then query 570 whether only one scan was necessary. If so, different GMR data sets need not be compiled, and the GMR profile may be compared 558 for identification of an irregularity. If more than one scan was needed 570, the different GMR data sets may first be compiled 568 into a single GMR profile before comparing 558 the GMR profile.

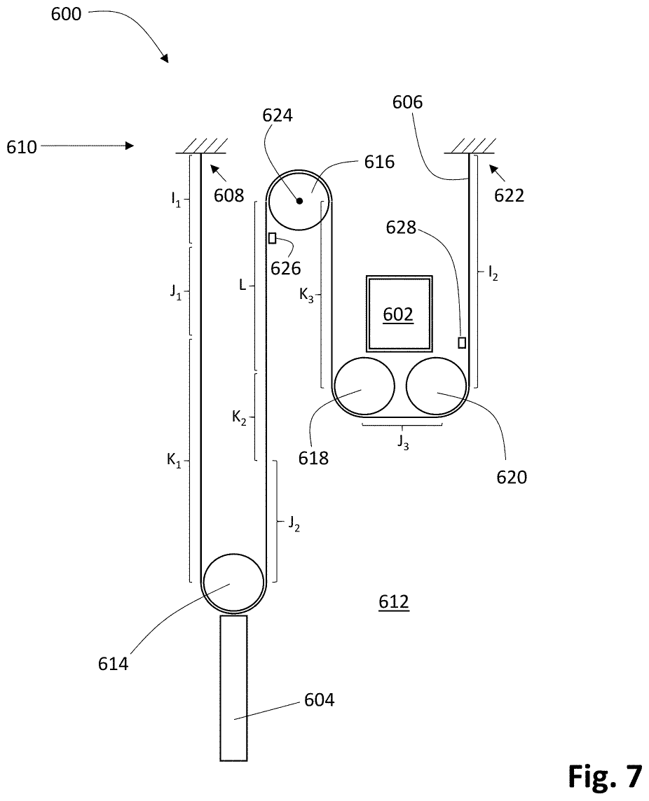

FIG. 7 schematically depicts yet another example elevator system 600. The elevator system 600 features 2:1 gearing unlike the elevator systems 100, 500 discussed above. It should be understood, though, that the aspects of the present disclosure described below are not limited to elevator systems with 2:1 gearing. Notwithstanding, the elevator system 600 may include an elevator car 602 and a tension unit 604 that are connected via a belt 606. The belt 606 may be fixed to a first anchor point 608 at a top 610 of a hoistway 612. The belt 606 may extend down from the first anchor point 608 around a first sheave 614 that is connected to the tension unit 604, up and around a second sheave 616, down around third and fourth sheaves 618, 620 that are connected to the elevator car 602, and up to a second anchor point 622 at the top 610 of the hoistway 612. The second sheave 616 may be configured as a drive sheave, which is turned by a hoisting motor 624 to move the belt 606. To reiterate, the figures throughout the present disclosure are merely schematic representations of various example systems and are not drawn to scale.

The elevator system 600 may further include a first monitoring system 626 for GMR scanning the belt 606. The first monitoring system 626 may be attached to or positioned near the second sheave 616. In some cases, the elevator system 600 may include a second monitoring system 628, which helps ensure that virtually the entire belt 606 (or the entire belt 606 depending on the placement of the second monitoring system 628) can be GMR scanned. In the example shown in FIG. 7, the second monitoring system 628 is attached to the elevator car 602 near the fourth sheave 620.

Those having ordinary skill in the art will recognize that different sections of the belt 606 will experience different degrees of wear. This much holds true even for the example belts 130, 230, 506 discussed above. One example factor that causes some sections of the belt 606 to experience a higher degree of wear than others is a number of different ways in which a section of the belt is bent, as will be described in further detail with respect to FIG. 7. Another example factor that corresponds with a higher degree of wear concerns a frequency with which a section of the belt 606 transitions between being straight and being wrapped (or “bent”) around a sheave. Yet another example high-wear factor concerns an amount of time that a section of the belt 606 spends idly wrapped around a sheave. For instance, if the elevator car 602 spends the majority of its idle time waiting for passengers on a first floor, sections of the belt 606 that are wrapped around the sheaves 614, 616, 618, 620 while the elevator car 602 is stationed at the first floor may experience a higher degree of wear than sections of the belt 606 that are straight while the elevator car 602 is stationed at the first floor. Another high-wear factor involves a frequency with which a section of the belt 606 is wrapped around a sheave when the elevator car 602 accelerates or decelerates. Of course this list of examples is illustrative and far from exhaustive.

An elevator control system of the elevator system 600 may continuously track the position of the elevator car 602 in the hoistway 612 relative to time for future reference. Tracking may in one example involve storing position versus time data for the elevator car 602 in a storage medium. Consequently, because the elevator control system knows the positions of the sheaves relative to the belt 606 based on the position of the elevator car 602, the elevator control system can identify the degree of wear to which each section of the belt 606 is subjected. In other words, based on the position of the elevator car 602 over time, the elevator control system knows the number of different ways in which each section of the belt 606 is bent, the frequency with which each section of the belt 606 transitions between being straight and being wrapped around a sheave, the amount of time that each section of the belt 606 spends idly wrapped around a sheave, the frequency with which each section of the belt 606 is wrapped around a sheave when the elevator car 602 accelerates or decelerates, and so on.

Knowing the degree of wear that each section of the belt 606 experiences is advantageous, especially when it comes to maintaining the safety of the elevator system 600. After all, an irregularity is more likely to occur in higher-wear sections of the belt 606 than in lower-wear sections. As a result, more resources can be dedicated to monitoring the integrity of high-wear sections of the belt 606. For instance, high-wear sections of the belt 606 can be scanned more frequently than low-wear sections. Likewise, more time can be allocated to scan high-wear sections of the belt 606 under ideal conditions than low-wear sections. It may also be the case that portions of the belt 606 adjacent to high-wear sections are scanned more frequently as well. Those having ordinary skill in the art should understand that even though the terms “low-wear” and “high-wear” are used in a somewhat binary fashion here, the degree of wear along the length of the belt 606 may be a continuum based on one or more of the example wear factors outlined above. Accordingly, the more wear a section of the belt 606 experiences, the more attention that section of the belt 606 may receive in terms of GMR monitoring, and vice versa.

To illustrate one of the example wear factors above, FIG. 7 shows how different sections of the belt 606 will be bent in different numbers of ways. Namely, sections I₁ and I₂ of the belt 606 will not be bent around any of the sheaves 614, 616, 618, 620, regardless of the positions of the elevator car 602 and the tension unit 604. Sections J₁, J₂, and J₃ will be bent at most once throughout the range of movement of the elevator car 602 and the tension unit 604. Sections K₁, K₂, and K₃ will be bent at most twice throughout the range of movement of the elevator car 602 and the tension unit 604. For example, when the elevator car 602 is lowered from the position shown in FIG. 7 and the tension unit 604 is raised, section K₂ will at some point be wrapped around the second sheave 616. Note that section K₂ will never reach the third sheave 618. When the elevator car 602 is raised from the position shown in FIG. 7, section K₂ will at some point be wrapped around the first sheave 614. Furthermore, section L of the belt 606 will be bent at most three times throughout the range of movement of the elevator car 602 and the tension unit 604. To be sure, section L will at times be wrapped around the second, third, and/or fourth sheaves 616, 618, 620.

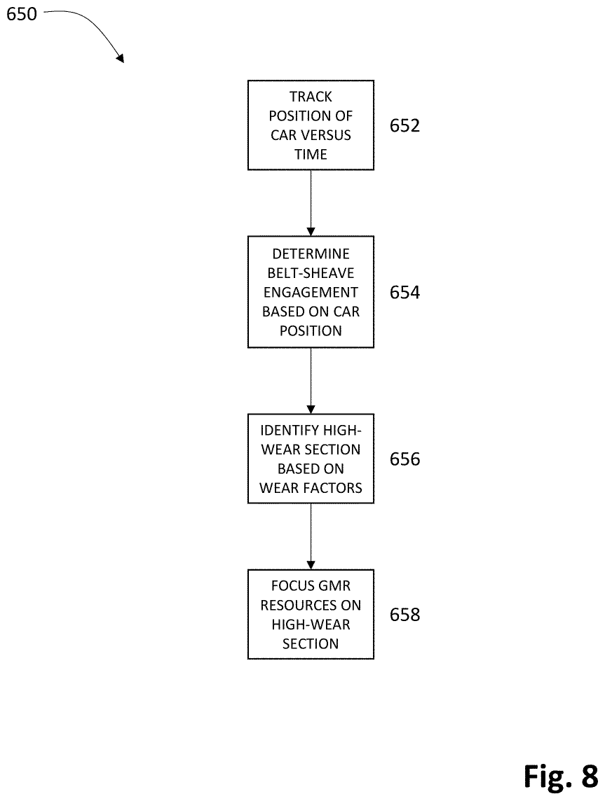

FIG. 8 illustrates one example method 650 for identifying high-wear sections of a belt. The method 650 includes at least some of the aspects of the present disclosure described above, and hence many of the aforementioned details will not be repeated. The method 650 is not limited to the steps recited below or those shown in FIG. 8, but may involve a variety of additional or alternative steps that all fall within the scope of the above disclosure. Nonetheless, the method 650 may comprise tracking 652 a position of an elevator car within a hoistway over time. An elevator control system may perform tracking 652 by storing position versus time data in a storage medium for an elevator car. The elevator control system may track 652 such data at all times after installation. From this tracking data, the elevator control system may have (or can at least deduce) a considerable amount of data about the elevator car's movements, such as the frequency at which the elevator car is located at each position within the hoistway, for instance. As another example, the elevator control system can determine when and where the elevator car typically accelerates and decelerates.

The example method 650 may further comprise determining 654 when a first section of the belt and when a second section of the belt engage with at least one sheave in the hoistway based on the position of the elevator car. In fact, the method 650 may involve determining which section of the belt is engaged with the sheave for each and every position in the hoistway to which the elevator car is configured to pass or travel. Because the elevator car is fixed along the length of the belt, because the first and second sections of the belt are fixed relative to the elevator car, and because the length of the belt may be considered to be fixed for purposes of explaining this method 650, the elevator control system can thus also determine a considerable amount of information about the first and second sections of the belt engaging with the sheave. More specifically, the elevator control system may be able to determine, for example and without limitation, the number of different ways in which the first and second sections of the belt are bent (which may depend on the number of sheaves utilized), the frequency with which each section of the belt transitions between being straight and being wrapped around the sheave, the amount of time that each section of the belt spends idly wrapped around the sheave, the frequency with which each section of the belt is wrapped around the sheave when the elevator car accelerates or decelerates, and so on.

The example method 650 may additionally involve identifying 656 whether the first section of the belt or the second section of the belt experiences a higher degree of wear based on at least one of the example wear factors enumerated above. In some cases, the elevator control system may determine which section experiences more wear by using a combination or even all of these factors. Last but not least, the method 650 may comprise focusing GMR scanning resources on the higher-wear section rather than the other section that experiences less wear. As one example, the section that experiences more wear may be GMR scanned five times per day as opposed to the other section that may be GMR scanned once per day.

Those having ordinary skill in the art will understand that the example method 650 is not limited to identifying merely one section of a belt that experiences high wear. Rather, the method 650 can be employed to identify a degree of wear across the full length of the belt. This may occur on a very granular level, such as millimeter by millimeter along the length of the belt, for instance. The present disclosure only references two sections of the belt for ease of explanation. GMR scanning resources can then be allocated relative to the respective level of wear for each respective section of the belt.

Again, those with ordinary skill in the art will readily understand that the disclosure relating to some examples may be combined with and/or equally applicable to the disclosure relating to other examples. As merely one example, one of the methods disclosed above could be used to identify high-wear sections of the belt based on, for instance, a frequency with which each section of the belt transitions between being straight and being engaged with a sheave, an amount of time that each section of the belt spends idly wrapped around the sheave, or a frequency with which each section of the belt is engaged with the sheave when an elevator car accelerates or decelerates. Once the high-wear sections of the belt are identified, a GMR monitoring system could perform scans of the high-wear sections of the belt (or subsets thereof) while the elevator car moves to pick up or transport passengers. Data acquired during different runs of the elevator car could be compiled into a GMR profile that is then analyzed to determine whether any of the high-wear sections of the belt contain an irregularity.

What is claimed is:

1. A method for monitoring integrity of a belt of an elevator system, the method comprising steps of:
moving an elevator car between floors of a building in a first run to pick up or transport a first passenger;
performing during the first run a first scan of a first segment of a belt from which the elevator car is suspended;
moving the elevator car between floors of the building in a second run to pick up or transport the first passenger or a second passenger, wherein in the second run the elevator car passes or accesses at least one floor that is not passed or accessed in the first run;
performing during the second run a second scan of a second segment of the belt that is at least partially different than the first segment of the belt;
compiling data from the first and second scans into a profile; and
analyzing the profile to determine whether the belt contains an irregularity.

2. The method of claim 1 comprising continuing to perform one or more additional scans while moving the elevator car to pick up or transport one or more passengers at least until the elevator car has traveled to or passed by all floors to which the elevator car has access, wherein data from the one or more additional scans corresponds at least to a third segment of the belt that is different than the first and second segments of the belt, wherein the data from the one or more additional scans is compiled into the profile before the profile is analyzed.

3. The method of claim 1 wherein performing each of the first and second scans comprises:
passing load bearing members of the belt that contain magnetic material through a magnetic field; and
sensing variations in the magnetic field at points along a length of the belt as the belt moves relative to the magnetic field.

4. The method of claim 1 wherein the profile comprises values for points along a length of the belt, wherein analyzing the profile comprises comparing the values for the points along the length of the belt to corresponding values from a prior profile that was acquired prior to the first and second runs.

5. The method of claim 4 wherein the prior profile is acquired before the elevator car is suspended from the belt.

6. The method of claim 4 wherein the prior profile is acquired before the elevator system is approved for passenger use but after the elevator car is suspended from the belt.

7. The method of claim 1 wherein all the steps are completed in a first period and all the steps are repeated in a second period, wherein during each of the first and second periods the method comprises continuing to perform additional scans while moving the elevator car to transport or pick up passengers, wherein prior to an end of each period the method comprises taking the elevator car out of service and performing a supplemental scan while the elevator car travels to or passes by all remaining floors of the building that the elevator car has not yet traveled to or passed by during the respective period, wherein the profile for each respective period comprises data from the respective first scan, the respective second scan, the respective additional scans, and the respective supplemental scan.

8. The method of claim 1 wherein the profile comprises values for points along a length of the belt, wherein analyzing the profile comprises comparing the values for the points along the length of the belt to corresponding values that have been averaged from a plurality of prior profiles that were acquired prior to the first and second runs.

9. The method of claim 1 wherein the profile comprises values for points along a length of the belt, wherein analyzing the profile comprises comparing each of the values to an average or a median of the values for the points along the length of the belt.

10. The method of claim 1 comprising taking the elevator car out of service and performing another scan for a point along the belt when the analysis of the profile determines that the point contains an irregularity.

11. A method for monitoring integrity of a belt of an elevator system, wherein the elevator system comprises a belt from which an elevator car is suspended, the belt having a first segment that passes a stationary sensor unit when the elevator car travels between a first floor and a second floor, a second segment that passes the stationary sensor unit when the elevator car travels between the second floor and a third floor, and a third segment that passes the stationary sensor unit when the elevator car travels between the third floor and a fourth floor, the method comprising:
scanning the first, second, and third segments of the belt with the stationary sensor unit in a first period to generate a first profile, wherein the first, second, and third segments of the belt are irregularity-free in the first period;
scanning the first, second, and third segments of the belt with the stationary sensor unit while the elevator car is moving to transport or to pick up passengers during runs in a second period;
compiling a second profile based on data for the first, second, and third segments of the belt acquired during the second period; and
comparing the second profile with the first profile to identify whether the belt contains an irregularity.

12. The method of claim 11 wherein compiling the second profile comprises averaging duplicative data acquired by the stationary sensor unit in the second period, wherein the duplicative data exists for points along a length of the belt that are scanned more than once during the second period.

13. The method of claim 11 comprising taking the elevator car out of service and scanning the third segment of the belt before an end of the second period if the elevator car has yet to move between or past the third floor and fourth floors before the end of the second period.

14. The method of claim 11 wherein the first and second profiles comprise values for points along a length of the belt, wherein the values for the second profile are compared to corresponding values that have been averaged from a plurality of prior profiles that were acquired prior to the second period, wherein the first profile from the first period is one of the plurality of prior profiles.

15. The method of claim 11 comprising compiling the first profile based on data for the first, second, and third segments of the belt acquired during the first period.

16. An elevator system comprising:
an elevator car that is movable within a hoistway;
a tension unit;
a belt with load bearing members that connects the elevator car to the tension unit, wherein the tension unit generates tension in the belt, wherein the belt is configured to move the elevator car between floors that are accessible via the hoistway;
a sheave around which the belt is wrapped;
a first monitoring system that scans a first segment of the belt while the elevator car is moving to pick up or to transport a passenger for a first passenger trip and scans a second segment of the belt while the elevator car is moving to pick up or to transport a passenger for a second passenger trip, wherein the first and second segments of the belt are at least partially different; and
an elevator control system that compares a first profile of the belt to a second profile of the belt to determine whether the belt contains an irregularity, wherein the first profile is acquired at a time when the belt is irregularity-free, wherein the second profile is compiled from the scans of the first and second segments of the belt.

17. The elevator system of claim 16 wherein the first monitoring system is disposed at the sheave to minimize vibration of the belt as the belt moves past the monitoring system.

18. The elevator system of claim 17 comprising a second monitoring system that is disposed at the sheave and is spaced apart from the first monitoring system, wherein the second monitoring system is configured to scan a part of the belt that does not pass by the first monitoring system.

19. The elevator system of claim 16 wherein the first monitoring system comprises a sensor unit with a magnetic field producer and a sensor, the sensor being configured to continuously monitor variations in the magnetic field while the elevator car is moving.

20. The elevator system of claim 16 wherein the first monitoring system is a first giant magneto-resistance monitoring system.
